(19) United States
(12) Patent Application Publication
(10) Pub. No.: US 2009/0072226 A1
(43) Pub. Date: Mar. 19, 2009

(54) DISPLAY DEVICE HAVING ORGANIC THIN FILM TRANSISTOR

(75) Inventors: Jae-Bon Koo, Daejeon (KR); Seung-Youl Kang, Daejeon (KR); Kyung-Soo Suh, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/112,646

(22) Filed: Apr. 30, 2008

(30) Foreign Application Priority Data
Sep. 18, 2007 (KR) 10-2007-0094554

(51) Int. Cl. H01L 51/30

(52) U.S. Cl. 257/40; 257/E51.007

(57) ABSTRACT

Provided is a display device having an organic TFT. The display device includes the organic TFT on a substrate, a passivation layer covering the organic TFT, and a bank layer on the passivation layer. At this point, at least one of the passivation layer and the bank layer is formed of a material blocking light incident from a portion on the substrate to the organic TFT.

### CROSS-REFERENCE TO RELATED APPLICATIONS

This U.S. non-provisional patent application claims priority under 35 U.S.C. § 119 of Korean Patent Application No. 10-2007-94554, filed on Sep. 18, 2007, the entire contents of which are hereby incorporated by reference.

### BACKGROUND OF THE INVENTION

The present invention disclosed herein relates to a display device, and more particularly, to a display device having an organic thin film transistor.

The present invention has been derived from a research conducted as a part of the information technology (IT) new growth power core technology development business by Ministry of Information and Communication, and Institute for Information Technology Advancement, Republic of Korea (Project management No.: 2005-S-070-03, Project title: flexible display).

A thin film transistor (TFT) is used as a switching device or a driving device in a flat panel display device such as a liquid crystal display (LCD), an organic light emitting diodes (OLED) display, and an inorganic LED display. The switching device controls the operation of each pixel of the flat panel display device, and the driving device drives each pixel.

Meanwhile, if the threshold voltage of the switching device changes, the gate voltage of the driving device applied through the switching device may change, and therefore, the gray characteristic of the pixel is difficult to realize precisely. Also, the change in the threshold voltage of the driving device causes a change in a turn-on current characteristic determining the brightness of a pixel. In this aspect, to improve the gray and brightness characteristics of a pixel, the switching device and the driving device need to have a stable electrical characteristic.

A recently proposed organic TFT can be manufactured using a very cheap process technology such as a printing technique and a typical semiconductor process technology. In addition, the organic TFT can be manufactured on a flexible substrate such as a plastic substrate, because it can be formed by using low temperature process technology. Accordingly, it is expected that the organic TFT can be used as an active device for a large-sized flat panel display device or recently spotlighted flexible electronic products in substitution for an inorganic TFT such as a polysilicon TFT. For example, an OLED display using the organic TFT as an active device has a fast response time of 1 ms or less, and moreover, it has excellent technical characteristics related to visibility and a viewing angle. Also, since the OLED display does not require a backlight, it has a lower power consumption characteristic and a thinner thickness than those of an LCD. Accordingly, the OLED display is in the limelight as a next generation flat panel display device that will replace an LCD widely used recently.

However, the threshold voltage and the mobility of a typical organic TFT are sensitive to a change in an environmental factor such as light. For example, as illustrated in FIG. 10, when a typical organic TFT is exposed to white visible light for six minutes, a change in a threshold voltage is about 28 V, which is an excessively large value. Due to this large change in the threshold voltage, it is difficult for a flat panel display device having a typical organic TFT to satisfy the required gray and brightness characteristics.

### SUMMARY OF THE INVENTION

The present invention provides a display device having an organic TFT providing a stable threshold voltage.

The present invention also provides a display device having an organic TFT that can reduce fluctuation of a threshold voltage caused by light.

Embodiments of the present invention provide display devices including: a substrate; an organic TFT on the substrate; and a light blocking layer on the substrate to block light incident to the organic TFT.

In other embodiments of the present invention, the organic TFTs include: a gate pattern on the substrate to block light incident from the lower portion of the substrate; a dielectric layer on the gate pattern; and an organic semiconductor layer on the dielectric layer. The light blocking layer is disposed on the organic TFT.

In some embodiments, the display devices further include a passivation layer on the organic TFT, an anode electrode on the passivation layer, and a bank layer on the passivation layer to cover the edge of the anode electrode. In this case, at least of the passivation layer, the anode electrode, and the bank layer is used as the light blocking layer.

In other embodiments, at least one of the passivation layer and the bank layer includes at least one combination of metal oxides, metal nitrides, organic dielectrics, and polyimide-based resins that is configured to provide light transmittance of 5% or less. At least one of the passivation layer and the bank layer includes at least one of oxides of metal materials and carbon black-doped organic dielectrics.

In still other embodiments, the anode electrode is formed to cover the upper surface of the passivation layer in the upper region of the organic TFT to effectively prevent light incident from a portion on the substrate from being incident to the organic TFT. The anode electrode includes at least one of metal materials.

In even other embodiments, the display devices further include an upper light blocking layer on the organic semiconductor layer and formed of a material that may provide light transmittance of 5% or less. The upper light blocking layer is used as the light blocking layer.

In yet other embodiments, the organic TFT further includes source/drain patterns covering the upper surface of the dielectric layer on the edges of the gate pattern. The source/drain patterns extend between the dielectric layer and the organic semiconductor layer, or extend on the edge of the organic semiconductor layer.

In further other embodiments, the organic TFT includes an organic semiconductor layer on the substrate, a dielectric layer on the organic semiconductor layer, and a gate pattern on the dielectric layer to block light incident from a portion on the substrate. A lower light blocking layer used as the light blocking layer is further disposed between the organic semiconductor layer and the substrate. Source/drain patterns are further disposed on both sides of the organic semiconductor layer, respectively. The lower light blocking layer extends from the lower portion of the organic semiconductor layer and is interposed at least between the source/drain patterns and the substrate. The lower light blocking layer includes at least one combination of metal oxides, metal nitrides, organic dielectrics, and polyimide-based resins that is configured to provide light transmittance of 5% or less.

In still other embodiments, the display devices further include an OLED. The organic TFT is used as a driving device controlling a current supplied to the OLED, and as a switching device controlling the operation of the deriving device.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a circuit diagram illustrating the unit pixel of an OLED display according to an embodiment of the present invention.

FIGS. 2 through 9 are cross-sectional views illustrating the unit pixel of an OLED display according to embodiments of the present invention.

FIG. 10 is a graph showing the threshold voltage characteristic of an organic TFT caused by light.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, the dimensions of layers and regions are exaggerated for clarity of illustration. It will also be understood that when a layer (or film) is referred to as being ‘on’ another layer or substrate, it may be directly on the other layer or substrate, or intervening layers may also be present. Also, though terms like a first, a second, and a third are used to describe various regions and layers in various embodiments of the present invention, the regions and the layers are not limited to these terms. These terms are used only to tell one region or layer from another region or layer. Therefore, a layer referred to as a first layer in one embodiment may be referred to as a second layer in another embodiment. An embodiment described and exemplified herein includes a complementary embodiment thereof.

Hereinafter, an exemplary embodiment of the present invention will be described with the accompanying drawings.

Technical characteristics of an organic TFT according to the present invention will be described using an OLED display for an example. However, the spirit of the present invention is not limited to the OLED display in that the organic TFT is not solely used for the exemplified OLED display.

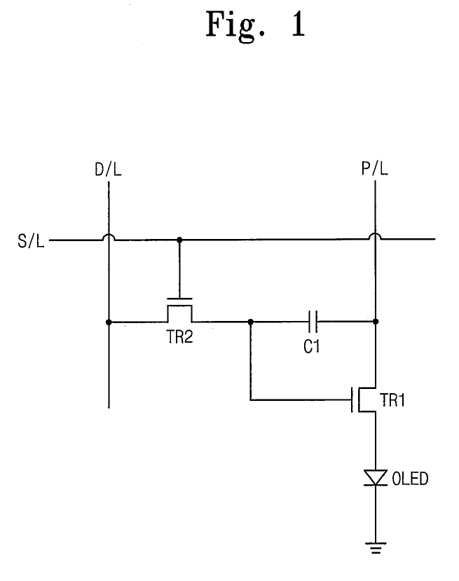

FIG. 1 is a circuit diagram illustrating the unit pixel of an OLED display according to an embodiment of the present invention.

Referring to FIG. 1, the unit pixel of the OLED display includes a driving TFT TR1 connected to an OLED, and a switching TFT TR2 having a drain electrode connected to the gate electrode of the driving transistor TR1. According to the present invention, each of the driving TFT TR1 and the switching TFT TR2 may be an organic TFT using an organic semiconductor layer as an active layer.

The source electrode and the gate electrode of the switching TFT TR2 are connected respectively to a data line D/L and a scan line S/L crossing each other. In addition, the source electrode of the driving transistor TR1 is connected to a power line P/L crossing the scan line S/L. The drain electrode of the switching transistor TR2 and the gate electrode of the driving transistor TR1 are capacitively coupled to the power line P/L through a capacitor C1.

At this point, the capacitor C1 allows a potential applied from the data line D/L to be maintained during a time interval (i.e., one frame) between selection signals of the scan line S/L. Also, the driving transistor TR1 is turned on by charges stored in the capacitor C1 to deliver power supplied from the power line P/L to the OLED. Therefore, when the threshold voltages of the switching transistor TR1 and the driving transistor TR2 change, the optical characteristic of the pixel may change. In this respect, the switching transistor TR1 and the driving transistor TR2 need to have a stable threshold voltage characteristic.

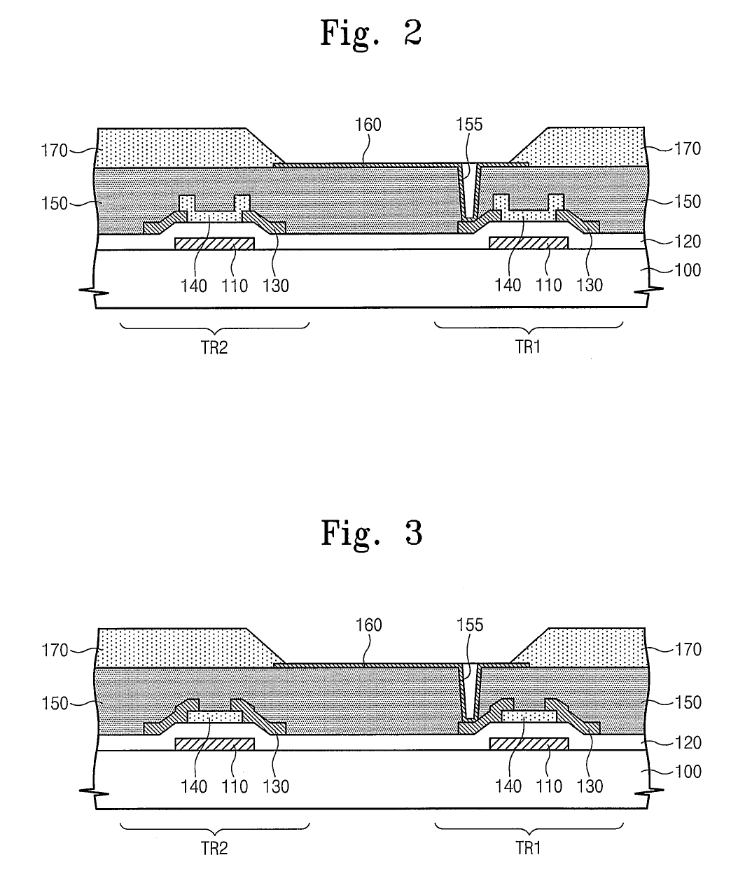

According to the present invention, at least one light blocking layer that may prevent fluctuation in the threshold voltage caused by light from the outside or inside is disposed on or under the driving and switching transistors TR1 and TR2. Various embodiments related to the light blocking layer will be described with reference to FIGS. 2 through 7.

FIG. 2 is a cross-sectional view illustrating the unit pixel of an OLED display according to an embodiment of the present invention.

Referring to FIG. 2, gate patterns 110 are disposed in predetermined regions on a substrate 100, and a dielectric layer 120 is disposed on a resulting structure where the gate patterns 110 have been formed. The gate patterns 110 and the dielectric layer 120 are used as the gate electrodes and the gate dielectrics of the driving transistor and the switching transistor TR1 and TR2, respectively.

Source/drain patterns 130 exposing portions of the dielectric layer 120 corresponding to the gate patterns 110 are disposed on the dielectric layer 120. Organic semiconductor layers 140 used as the active layers of the driving transistor and the switching transistor TR1 and TR2 are disposed on the exposed portion of the dielectric layer 120 on the gate patterns 110. The organic TFT having this structure is called a bottom gate-bottom contact or inverted coplanar structure TFT.

According to an embodiment, the substrate 100 may be formed of glass material, or formed of a flexible material such as plastic to realize a flexible OLED display.

The gate patterns 110 are formed of at least one of conductive materials that may block light incident to the organic semiconductor layer. For example, the gate patterns 110 may be formed of at least one of metal materials such as Mg, Al, Cr, Co, Ni, Pd, Ag, Au, Pt, Mo, and Ti, and compounds thereof. The gate patterns 110 may be formed in a single layer structure or a multi-layered structure. At this point, the gate pattern 110 may be formed to have light transmittance of about 5% or less. For example, a method of increasing the thickness of the gate pattern 110 may be used to achieve such a characteristic.

The dielectric layer 120 electrically separates the gate patterns 110 from the source/drain patterns 130, and may be formed of at least one of inorganic materials such as a silicon oxide and a silicon nitride, or at least one of organic materials such as polyvinyl phenol (PVP) and acryl-based polymer materials.

Also, the source/drain patterns 130 are formed of at least one of conductive materials. For example, the source/drain patterns 130 may be formed of at least one of metal materials such as Au, Pt, Pd, Ni, Cr, Al, Ag, Mo, and Ti, and compounds thereof. More specifically, the source/drain patterns 130 may include a lower metal layer directly contacting the dielectric layer 120, and an upper metal layer formed on the lower metal layer to improve a contact characteristic with the dielectric layer 120. According to one embodiment of the present invention, the lower metal layer may be formed of one of Ti, Al, and Cr. The upper metal layer may be formed of one of Au, Pt, Pd, and Ni. According to this embodiment, the source/drain patterns 130 may be also formed of a material that may prevent light.

The organic semiconductor layer 140 may include at least one of pentacene, tetracene, anthracene, naphthalene, α-6-thiophene, α-4-thiophene, perylene, rubrene, polythiophene, poly(p-phenylene vinylene (PPV), polyparaphenylene, polyfluorenes (PFs), polythiophenevinylene, polythiophene-heterocyclic aromatic copolymer, oligoacene of naphthalene oligothiophene of α-5-thiophene, metal phthalocyanine, metal-free phthalocyanine, and derivatives thereof.

In addition, a passivation layer 150 and a bank layer 179 are sequentially formed on the resulting structure where the driving transistor TR1 and the switching transistor TR2 have been formed. Also, an anode pattern 160 connected to the source/drain pattern 130 of the driving transistor TR1 through a contact hole 155 passing through the passivation layer 150 is formed on the passivation layer 150.

The passivation layer 150 allows the main top surface of the anode pattern 160 to be planarized while separating the anode pattern 160 from the switching transistor TR2. The bank layer 170 has a sloped sidewall profile and covers an upper edge of the anode pattern 160 to prevent an OLED to be formed on the anode pattern 160 from being open or short-circuited. In this respect, the bank layer 170 defines the shape of a pixel of an OLED display.

According to this embodiment, the passivation layer 150 may include at least one of metal oxides, metal nitrides, organic dielectrics, and polyimide-based resins, and is formed of a material that may have low light transmittance. More specifically, the passivation layer 150 may be formed of a material having light transmittance of about 5% or less. For example, the passivation layer 150 may be formed of a compound (e.g., oxides) of metal materials such as Mg, Al, Cr, Co, Ni, Pd, Ag, Au, Pt, Mo, and Ti. Also, the passivation layer 150 may be one of carbon black-doped organic dielectrics. However, the kind of a material that may be used for the passivation layer 150 is not limited to the examples described herein.

The bank layer 170 may be formed of at least one of polyacryl-based organic materials and polyimide-based materials. Also, the anode pattern 160 may include at least one of transparent conductive materials such as indium-tin-oxide (ITO), indium-zinc-oxide (IZO), and ZnO, and metal materials such as Ag, Al, Mg, Ni, and Cr. For example, in the case where the anode pattern 160 is used as a transparent electrode, it may be formed of at least one of ITO, IZO, and ZnO. In the case where the anode pattern 160 is used as a reflective electrode, it may be formed in a multi-layered structure in which at least one of ITO, IZO, and ZnO is stacked on at least one of metal materials such as Ag, Al, Mg, Ni, and Cr.

Meanwhile, the substrate 100, the gate pattern 110, the dielectric layer 120, the source/drain patterns 130, the organic semiconductor layer 140, the passivation layer 150, the anode pattern 160, the bank layer 170, and an interface pattern 200 are not limited to the above-described materials. Various materials known in the art may be readily used for these elements.

FIG. 3 is a cross-sectional view illustrating the unit pixel of an OLED display according to another embodiment of the present invention. This embodiment is similar to the embodiment described with reference to FIG. 2 with a difference in the sequence of stacking the organic semiconductor layer 140 and the source/drain patterns 130. Therefore, descriptions for the same parts are omitted for concise explanation.

Referring to FIG. 3, according to this embodiment, organic semiconductor layers 140 used as the active layers of a driving transistor TR1 and a switching transistor TR2 are disposed on a dielectric layer 120 on gate patterns 110. Also, source/drain patterns 130 covering the upper edges of the organic semiconductor layers 140 are disposed on the dielectric layer 120. The organic TFT having this structure is called a bottom gate-bottom contact or inverted staggered structure.

According to this embodiment, like the inverted coplanar structure described with reference to FIG. 2, the gate pattern 110 is interposed between the substrate 100 and the organic semiconductor layer 140. Therefore, the gate pattern 110 is formed of at least one of materials capable of providing low light transmittance, thereby preventing light incident from a portion below a substrate 100 from reaching the organic semiconductor layer 140. For example, like the previous embodiment, the gate patterns 110 may be formed of at least one of metal materials such as Mg, Al, Cr, Co, Ni, Pd, Ag, Au, Pt, Mo, and Ti, and compounds thereof. The gate patterns 110 may be formed in a single layer structure or a multi-layered structure.

In addition, a passivation layer 150 may include at least one of metal oxides, metal nitrides, organic dielectrics, and polyimide-based resins. The passivation layer 150 is formed of a material that may provide low light transmittance. More specifically, the passivation layer 150 may be formed of a material having light transmittance of about 5% or less. For example, the passivation layer 150 may be formed of a compound (e.g., oxides) of metal materials such as Mg, Al, Cr, Co, Ni, Pd, Ag, Au, Pt, Mo, and Ti. Also, the passivation layer 150 may be one of carbon black-doped organic dielectrics. However, the kind of a material that may be used for the passivation layer 150 is not limited to the examples described herein.

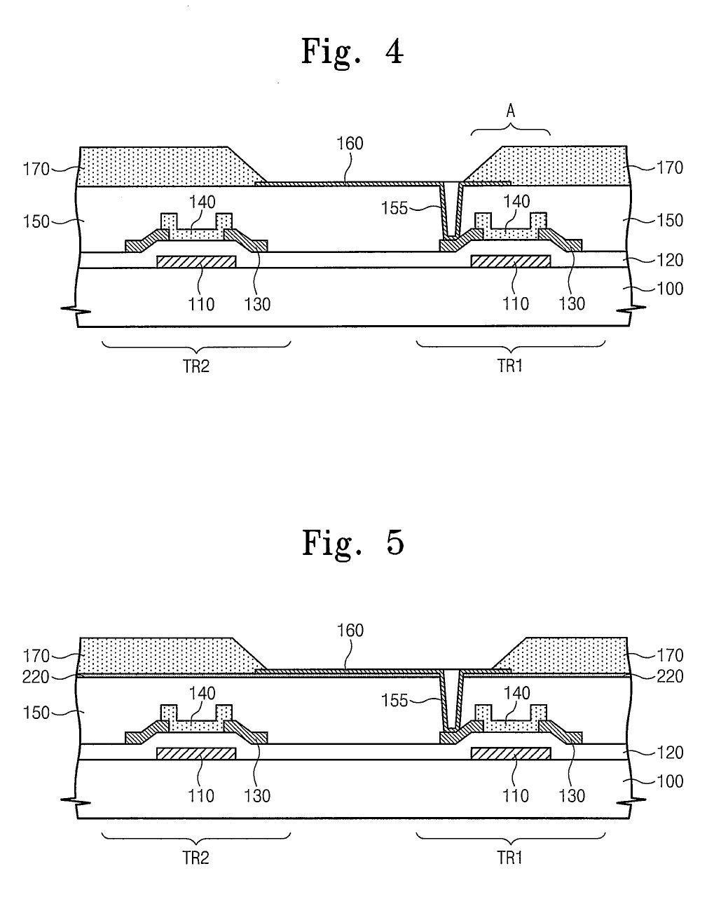

FIG. 4 is a cross-sectional view illustrating the unit pixel of an OLED display according to still another embodiment of the present invention. This embodiment is similar to the embodiment described with reference to FIG. 2 with a difference that a bank 170 is formed of a material having a light blocking characteristic. Therefore, descriptions for the same parts are omitted for concise explanation.

Referring to FIG. 4, according to this embodiment, the bank layer 170 is formed of a material that may have a low light transmittance characteristic. More specifically, the bank layer 170 may be formed of a material having light transmittance of 5% or less. For example, the bank layer 170 may include at least one of polyacryl-based resins, polyimide-based resins, metal oxides, metal nitrides, and organic dielectrics. More specifically, the bank layer 170 may be at least one of compounds (e.g., oxides) of metal materials such as Mg, Al, Cr, Co, Ni, Pd, Ag, Au, Pt, Mo, and Ti, and carbon black-doped organic dielectrics. However, the kind of a material that may be used for the bank layer 170 is not limited to the examples described herein.

Meanwhile, according to this embodiment, to effectively block light incident from a portion on a substrate 100, the bank layer 170 may be disposed to cover an anode pattern 160 or a passivation layer 150 in an area A on an organic semiconductor layer 140, as illustrated.

In this case, the passivation layer 150 may be formed of at least one of metal oxides, metal nitrides, organic dielectrics, and polyimide-based resins, and may be formed of a material having low light transmittance. However, according to other embodiments, the passivation layer 150 may not be limited to a technical requirement related to the light transmittance. That is, the passivation layer 150 may be formed of a material having relatively greater light transmittance than that of the bank layer 170.

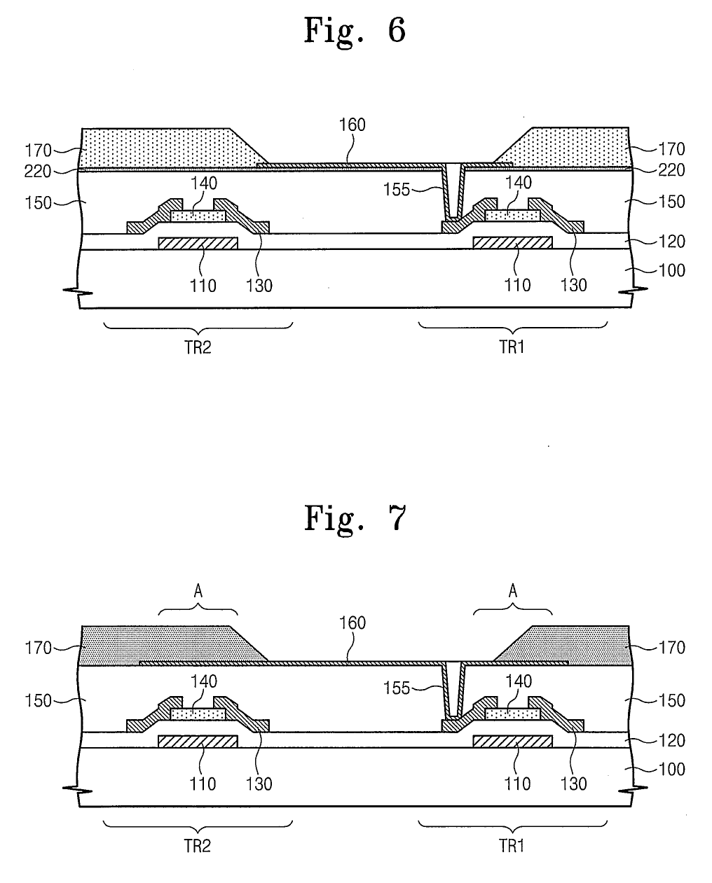

FIGS. 5 and 6 are cross-sectional views illustrating the unit pixel of an OLED display according to modifications of the embodiments of the present invention. According to these embodiments, an additional upper light blocking layer 220 is formed on a passivation layer 150. With this difference excluded, these embodiments are similar to the previous embodiments described with reference to FIGS. 2 and 3. Therefore, descriptions for the same parts are omitted for concise explanation.

Referring to FIGS. 5 and 6, the additional upper light blocking layer 220 is formed on the passivation layer 150. According to an embodiment, the upper light blocking layer 220 is formed to cover at least a region on an organic semiconductor layer 140 used as the active layers of a driving transistor TR1 and a switching transistor TR2. At this point, the upper light blocking layer 220 may extend between the passivation layer 150 and an anode pattern 160, or between the passivation layer 150 and a bank layer 170.

Meanwhile, the upper light blocking layer 220 is formed of a material having low light transmittance. More specifically, the upper light blocking layer 220 may be formed of a material having light transmittance of 5% or less. For example, the upper light blocking layer 220 may include at least one of metal oxides, metal nitrides, organic dielectrics, and polyimide-based resins. More specifically, the upper light blocking layer 220 may be formed of compounds (e.g., oxides) of metal materials such as Mg, Al, Cr, Co, Ni, Pd, Ag, Au, Pt, Mo, and Ti. Also, the upper light blocking layer 220 may be one of carbon black-doped organic dielectrics. However, the kind of a material that may be used for the upper light blocking layer 220 is not limited to the examples described herein.

According to this embodiment, the passivation layer 150 and a bank layer 170 may be formed of at least one of materials having low light transmittance as described with reference to FIGS. 2 and 3. However, in the case where the upper light blocking layer 220 may effectively block light incident from a portion on the substrate 100, the passivation layer 150 and the bank layer 170 do not need to be formed of materials having low light transmittance.

FIG. 7 is a cross-sectional view illustrating the unit pixel of an OLED display according to a modification of the previous embodiment of the present invention. According to this embodiment, the anode pattern 160 is used as a light blocking layer. Descriptions for the same parts are omitted for concise explanation.

Referring to FIG. 7, an anode pattern 160 is formed of at least one of metal materials so that it may be used as a reflective electrode. For example, the anode pattern 160 may include at least one of metal materials such as Ag, Al, Mg, Ni, and Cr. At least one of ITO, IZO, and ZnO may be staked on the anode pattern 160.

Since the anode pattern 160 reflects incident light when it is formed of a metal material, it may prevent external light from being incident to an organic semiconductor layer 140 below the anode pattern 160. Therefore, a passivation layer 150 and a bank layer 170 do not need to meet a technical requirement proposed in the previous embodiments related to light transmittance. That is, the passivation layer 150 and the bank layer 170 may be formed of materials having relatively large light transmittance. However, even in this embodiment, the passivation layer 150 and the bank layer 170 may be formed of materials that can meet a technical requirement related to the light transmittance proposed by the previous embodiments.

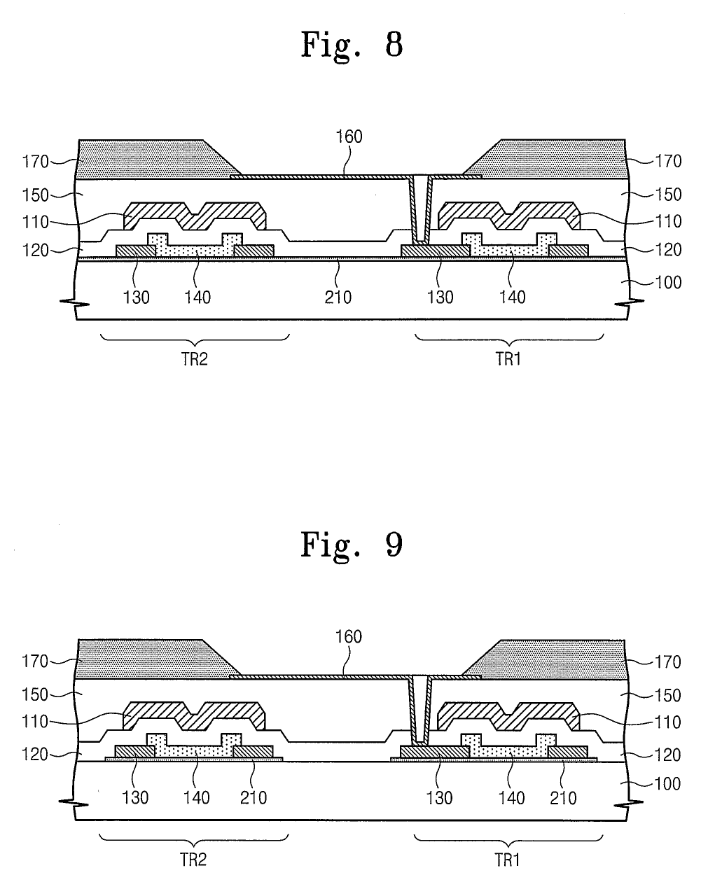

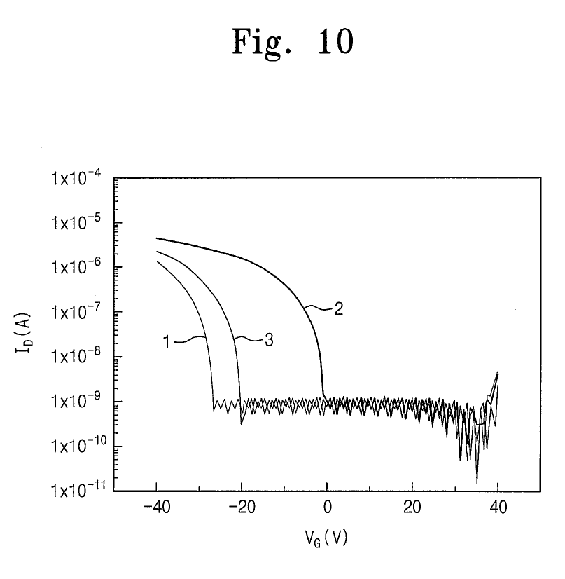

FIG. 8 is a cross-sectional view illustrating the unit pixel of an OLED display according to still another embodiment of the present invention, and FIG. 9 is a cross-sectional view illustrating a modification of the embodiment of FIG. 8. These embodiments are similar to the previous embodiments described with reference to FIGS. 2 through 4 with differences in the sequence of stacking a gate pattern, an organic semiconductor layer, a dielectric layer, and source/drain patterns, and in the kind of a material that may be used for a passivation layer. Therefore, descriptions for the same parts are omitted for concise explanation.

Referring to FIGS. 8 and 9, according to this embodiment, source/drain patterns 130 separated from each other are disposed in a predetermined region of a substrate 100. Organic semiconductor layers 140 used as the active layers of a driving transistor TR1 and a switching transistor TR2 are disposed between the source/drain patterns 130. A dielectric layer 120 is disposed on a resulting structure where the organic semiconductor layers 140 have been formed. Gate patterns 110 are disposed on portions of the dielectric layer 120 on the organic semiconductor layers 140. The gate patterns 110 and the dielectric layer 120 are used as the gate electrodes of the driving transistor TR1 and the switching transistor TR2, and a gate dielectric. The organic TFT having this structure is called a staggered structure.

In these embodiments, the gate patterns 110 are formed of at least one of materials that may provide low light transmittance. For example, like the previous embodiments, the gate patterns 110 may be formed of at least one of metal materials such as Mg, Al, Cr, Co, Ni, Pd, Ag, Au, Pt, Mo, and Ti, and compounds thereof. The gate patterns 110 may be formed in a single layer structure or a multi-layered structure. In this case, it is possible to prevent light incident from a portion on the substrate 100 from reaching the organic semiconductor layer 140.

Meanwhile, a lower light blocking layer 210 may be further disposed between the organic semiconductor layer 140 and the substrate 100. For example, as illustrated in FIG. 8, the lower light blocking layer 210 may be formed to extend from the organic semiconductor layer 140 to cover the entire surface of the substrate 100. Alternatively, as illustrated in FIG. 9, the lower light blocking layer 210 may extend from the organic semiconductor layer 140 to a portion under the source/drain patterns 130. At this point, the lower light blocking layer 210 may be simultaneously formed during a patterning operation of forming the source/drain patterns 130. In this case, as illustrated, the lower light blocking pattern 210 may be self-aligned on sidewalls of the source/drain patterns 130, and an additional pattering operation is not required. However, in the case where a region where the lower light blocking layer 210 is disposed includes a region under the organic semiconductor layer 140, a range in which the lower light blocking layer 210 extends may be modified in various ways.

According to these embodiments, the lower light blocking layer 210 is formed of a material that may have low light transmittance. More specifically, the lower light blocking layer 210 may be formed of a material having light transmittance of about 5% or less. For example, the lower light blocking layer 210 may include at least one of metal oxides, metal nitrides, organic dielectrics, and polyimide-based resins. More specifically, the lower light blocking layer 210 may be formed of compounds (e.g., oxides) of metal materials such as Mg, Al, Cr, Co, Ni, Pd, Ag, Au, Pt, Mo, and Ti. Also, the lower light blocking layer 210 may be one of carbon black-doped organic dielectrics. However, the kind of a material that may be used for the lower light blocking layer 210 is not limited to the examples described herein.

Meanwhile, in the case where the gate pattern 110 is formed of a transparent conductive material in the embodiments described with reference to FIGS. 2 through 7, the lower light blocking layer 210 may be also used for these embodiments.

FIG. 10 is a graph measuring the threshold voltage characteristic of an organic TFT with respect to light. An experiment has been performed using an organic TFT using pentacene as an active layer. In the graph, a horizontal axis represents a voltage applied to a gate pattern, and a vertical axis represents a current flowing through a drain electrode.

Referring to FIG. 10, the organic TFT is maintained in a turn-on state for 10 minutes to allow a current to flow through it, and then a drain current of the organic TFT is measured while a gate voltage is swept from +40 V to −40 V. The curve of the reference numeral 1 in FIG. 10 shows a result of this measurement, and the threshold voltage was about −28 V.

The curve of the reference numeral 2 shows a voltage-current characteristic measured in the same manner after white visible light is illuminated for six minutes onto the organic TFT on which the measurement for the curve of the reference numeral 1 has been performed. In this case, the threshold voltage is about 0V. That is, in this case, there is a change of about 28 V in the threshold voltage compared to the case of reference numeral 1.

The curve of the reference numeral 3 shows a voltage-current characteristic measured in the same manner after maintaining the organic TFT, which the measurement for the curve of the reference numeral 1 has been performed on, in a light-blocked environment for six minutes. In this case, the threshold voltage is about −22 V. That is, in this case, there is a change of about 6 V in the threshold voltage compared to the case of reference numeral 1.

The experiments have showed that a change in a threshold voltage is very small in the case where light is blocked rather than the case where light is not blocked. Given that uniformity in a threshold voltage of the organic TFT sensitively depends on light, as proposed in the above-described embodiments, methods surrounding the organic semiconductor layer 140 using a light blocking material, males it possible to manufacture an organic TFT having a stable threshold voltage characteristic.

Meanwhile, though the embodiments where the technical features of the present invention have been applied to an OLED display having an organic TFT have been described in the above, the present invention may be readily applied to display devices where an organic TFT may be used such as LCDs, inorganic field-emission displays, and electrophoretic displays.

According to the present invention, a light blocking layer that may block light is formed on or under an organic TFT. As described with reference to FIG. 10, when light is incident to the organic TFT, the threshold voltage of the organic TFT excessively fluctuates, but the light block layer according to the present invention may reduce this fluctuation in the threshold voltage caused by light. Consequently, the organic TFT according to the present invention may have a stable electrical characteristic.

Particularly, in the case where the organic TFT having such a stable electrical characteristic is used as a switching transistor and a driving transistor of a display device, the display device may have improved gray and brightness characteristics.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A display device comprising:
a substrate;
an organic thin film transistor (TFT) on the substrate;
a passivation layer covering the organic TFT; and
a bank layer on the passivation layer to define a shape of a pixel, at least one of the passivation layer and the bank layer being formed of a material blocking light incident from a portion on the substrate to the organic TFT.

2. The display device of claim 1, wherein at least one of the passivation layer and the bank layer comprises at least one of group consisting of metal oxides, metal nitrides, organic dielectrics, and polyimide-based resins that is configured to provide light transmittance of 5% or less.

3. The display device of claim 1, wherein at least one of the passivation layer and the bank layer comprises at least one of oxides of Mg, Al, Cr, Co, Ni, Pd, Ag, Au, Pt, Mo, and Ti, and carbon black-doped organic dielectrics.

4. The display device of claim 1, wherein the passivation layer covers a portion on the organic TFT to block light incident from the portion on the substrate to the organic TFT.

5. The display device of claim 1, further comprising an anode electrode disposed on the passivation layer, the anode electrode covering an upper region of the organic TFT to block light incident from the portion on the substrate to the organic TFT.

6. The display device of claim 1, further comprising an upper light blocking layer on an organic semiconductor layer, the upper light blocking layer being formed of a material that provides light transmittance of 5% or less.

7. The display device of claim 1, wherein the organic TFT comprises:
gate patterns on the substrate;
a dielectric layer on the gate patterns; and
an organic semiconductor layer on the dielectric layer, the gate patterns being formed of a conductive material having low light transmittance to block light incident from a portion below the substrate to the organic semiconductor layer.

8. The display device of claim 7, wherein the organic TFT further comprises source/drain patterns covering the upper surface of the dielectric layer on the edges of the gate patterns, the source/drain patterns extending between the dielectric layer and the organic semiconductor layer, or extending on the edge of the organic semiconductor layer.

9. A display device comprising:
a substrate;
an organic semiconductor layer on the substrate;
a dielectric layer on the organic semiconductor layer;
gate patterns on the dielectric layer to block light incident from a portion on the substrate; and
a lower light blocking layer under the organic semiconductor layer to block light incident from a portion below the substrate.

10. The display device of claim 9, wherein the lower light blocking layer comprises at least one combination of metal oxides, metal nitrides, organic dielectrics, and polyimide-based resins that is configured to provide light transmittance of 5% or less.
